(19) United States
(12) Patent Application Publication
(10) Pub. No.: US 2015/0359099 A1
(43) Pub. Date: Dec. 10, 2015

(54) LOW AREA OVER-HEAD CONNECTIVITY SOLUTIONS TO SIP MODULE

(71) Applicant: Apple Inc., Cupertino, CA (US)

(72) Inventors: Shankar Pennathur, San Jose, CA (US); Dennis R. Pyper, San Jose, CA (US); Amir Salehi, San Jose, CA (US)

(21) Appl. No.: 14/296,449

(22) Filed: Jun. 4, 2014

(51) Int. Cl. H05K 1/18; H05K 3/36; H05K 3/30; H05K 1/11

(52) U.S. Cl. CPC H05K 1/181; H05K 1/189; H05K 1/115; H05K 3/363; H05K 3/303; H05K 2201/042; H05K 2201/10378

(57) ABSTRACT

Readily modifiable and customizable, low-area overhead interconnect structures for forming connections between a system-in-a-package module and other components in an electronic device. One example may provide an interposer for providing an interconnection between a system-in-a-package module and other components in an electronic device. Another may provide a plurality of conductive pins to form interconnect paths between a module and other components.

### BACKGROUND

The number of types of electronic devices that are commercially available has increased tremendously the past few years and the rate of introduction of new devices shows no signs of abating. Devices, such as tablet, laptop, netbook, desktop, and all-in-one computers, cell, smart, and media phones, storage devices, portable media players, navigation systems, monitors, and others, have become ubiquitous.

The functionality of these devices has likewise greatly increased. This in turn has led to increased complexity inside of these electronic devices. At the same time, the dimensions of these devices have become smaller. For example, smaller and thinner devices are becoming more popular.

This increasing functionality and decreasing size have necessitated the use of space-efficient circuit techniques. As one example, system-in-a-package modules and other similar structures may be used to increase an electronic device's functionality while reducing space consumed in the device.

These system-in-a-package modules may be connected to other boards, circuits or modules in an electronic device using connector systems. But connector systems may consume considerable board space on a module. They may also have a considerable height that may match or exceed a height of the module itself. Even direct connections, for example between a flexible circuit board and system-in-a-package module, may consume a large board area.

Moreover, connector systems may be difficult to modify when a design change to a module is necessary. Also, it may be difficult to acquire a customized connector system for a specific use. They may also be provided by third parties separate from a company that may manufacture the system-in-a-package modules and electronic devices. This separation may lead to further complications when a modified or custom connector system is desired.

Thus, what is needed are easily modifiable and customizable, low-area overhead interconnect structures for forming connections between a system-in-a-package module and other boards, circuits, or components in an electronic device.

### SUMMARY

Accordingly, embodiments of the present invention may provide readily modifiable and customizable, low-area overhead interconnect structures for forming connections between a system-in-a-package module and other boards, circuits, or components in an electronic device.

An illustrative embodiment of the present invention may provide an interposer for providing an interconnection between a first board and a second board. The first board may support or be part of a system-in-a-package module and the second board may provide an interconnect paths to other circuits or components in an electronic device. The interposer may include first contacts on a bottom surface and second contacts on a top surface. Interposer interconnect paths may be formed between the first contacts and the second contacts. The first contacts may be coupled to traces on a first board, the first board supporting a system-in-a-package module. Circuits and other components in the module may be coupled to the traces on the first board. Contacts on the second board may be coupled to the second contacts on the top of the interposer. Traces coupled to the contacts on the second board may couple to other boards, circuits, or components in an electronic device.

The interposer may be formed of various materials. For example, the interposer may be a printed circuit board formed of FR-4, BT, or other high-density substrate. The interposer may alternatively be formed of plastic or other material. The interconnect paths may be formed using traces on layers in the printed circuit board joined together with vias between layers of the board.

In this and other examples, the first board may be a printed circuit board, flexible circuit board, or other appropriate substrate. The second board may be a flexible circuit board, printed circuit board, or other appropriate substrate.

This interposer may provide a highly modifiable interconnect structure. Specifically, contact placement and the interconnect paths between the contacts may be readily modified using conventional printed circuit techniques. This interposer may also provide a highly customizability since its size, shape, and contact configurations may be readily arranged using these same conventional techniques. This may provide a high-degree of flexibility and configurability, in particular when compared to a convention connector system.

These interposers may also provide low-area overhead interconnect structures. Specifically, these interposers may be placed adjacent to a system-in-a-package module or other structure. Contacts on a bottom side of the interposer may be coupled to contacts on a first board supporting the module. The interposer may be adjacent to the module and the contacts may be very close to the module, thereby reducing the board space used. Contacts on a top side of the interposer may couple to traces in a second board, where the top of the interposer is at least approximately in a line with a top of the module. This configuration may eliminate or at least reduce the need for providing clearance or space between the second board and the module, again saving space.

In various embodiments of the present invention, the first contacts on a bottom of the interposer may be formed using ball grid array type contacts or similar structure. This may allow the interposer to be attached to the first board, such as a printed circuit board, at the same time as other surface-mounted devices and circuits. That is, the use of these or similar contacts may allow an interposer to be treated as another surface mount device during a wave soldering or other attachment process. The second contacts on a top side of the interposer may be attached to a second board, such as a flexible circuit board, using surface mount techniques, hot-bar soldering, anisotropic conductive film, or other attachment methods.

Various embodiments of the present invention may facilitate the connection of the second board to the interposer in different ways. In one specific embodiment of the present invention, the second board may overlap the interposer to cover at least a portion of the module. This may provide a larger area for forming a connection, which may be particularly useful when hot-bar soldering or similar attachment techniques are used.

In still other embodiments of the present invention, an interposer may be notched or stepped such that a top surface of the interposer is larger than a bottom surface of the interposer. This larger top surface may help to facilitate a connection of a second board to the top of the interposer. For example, contact size may be increased on the top surface. Also, additional contacts, for example additional ground or power contacts, may be placed on the top side to provide additional shielding or isolation.

In one embodiment of the present invention, an interposer may be notched or stepped such that the remaining module portion itself is stepped. This stepped portion of the module may result in a portion of the module having a lower height. In various embodiments of the present invention, appropriately sized components may be placed in this shallow or lower-height region in order to more fully utilize module space. In another embodiment of the present invention, an interposer may be notched or stepped such that a portion of the interposer resides over a top of the module. Again, this may provide a surface that may be easier to connect to a second board.

In still other embodiments of the present invention, the second board may be formed as part of the interposer. For example, a flexible board may be formed as one or more layers inside and extending from an interposer.

An illustrative embodiment of the present invention may provide an electronic device. The electronic device may include a first board, the first board having a number of interconnect traces. The first board may be a printed circuit board, flexible circuit board, or other type of board or appropriate substrate. A number of surface mount or other types of devices may be attached to a top surface of the first board. The surface mount devices may be electrically connected to traces on or in the first board. These surface mount devices may include active and passive components, integrated circuits, or other circuits or components. An interposer may be attached to the top surface of the first board. The interposer may be attached to the first board in the same or in a different manner as other surface mount devices. The interposer may be attached to the first board at the same or different time as the other surface mount devices. The interposer may have first contacts on a bottom surface electrically connected to traces in or on the first board. The interposer may further have a plurality of interconnect paths from the first contacts on the bottom surface to second contacts on a top surface. The interposer may be a multi-layer printed circuit board and the interposer interconnect paths may include contacts or traces on one or more layers and vias between at least two layers A simple interposer may have contacts on a top and bottom side that are connected using vertical vias. A second board having a number of traces or interconnect paths may be electrically connected to the second contacts on the top surface of the interposer. That is, contacts on the second board may connect to traces on and in the second board and to the second contacts on a top surface of the interposer. The second board may be a flexible circuit board, printed circuit board, or other appropriate board or substrate.

Again, the interposer may provide interconnection pathways to a system-in-a-package module. In this case, a molded portion made of plastic or other material may be formed over the surface mount devices on the top surface of the first board and along a side of the interposer. In other embodiments of the present invention, the first board is not part of a system-in-a-package module and the molded portion may not be present. In such a case, the interposer may be used to connect two conventional boards or one or more types. Also, while surface mount devices and interposers may be used, in other embodiments of the present invention, other types of devices and interposers may be used, for example through-hole devices and interposers may be used.

Another illustrative embodiment of the present invention may provide a method of manufacturing a portion of an electronic device. This method may include forming a first board comprising a number of traces. A number of surface mount or other types of devices may be attached to a top surface of the first board. The surface mount devices may be electrically connected to traces in the number of traces. An interposer may be attached to the top surface of the first board. The interposer may have first contacts on a bottom surface electrically connected to traces on the first board. The interposer may have a plurality of interconnect paths from the first contacts on the bottom surface to second contacts on a top surface. As before, the interposer may be a multi-layer printed circuit board and the interposer interconnects paths may include contacts or traces on at least one layer and vias between at least two layers. A molding made of plastic or other material may be formed over the surface mount devices and along a side of the interposer, though such molding may be absent in other embodiments of the present invention. A second board may have a number of traces such that the traces are electrically connected to the second contacts on the top surface of the interposer. Again, the first board may be a printed circuit board and the second board may be a flexible circuit board.

Other embodiments of the present invention may provide other interconnect structures for forming electrical paths between a system-in-a-package module and other circuits or components in an electronic device. In one example, a number of pins may be used. These pins may be formed in a localized area or array, or they may be distributed among other circuits or components. These pins may be surface mounted to a top of a first board along with a number of other surface mount circuits and components. The pins, circuits, and components may be encapsulated or covered with molded plastic or other material. The molding may be lapped back, etched, or otherwise reduced as needed such that tops of the pins are exposed. The pins may then be attached to a second board, such as a flexible circuit board, using surface mount techniques, hot-bar soldering, anisotropic conductive film, or other attachment methods. In various embodiments of the present invention, not all pins may be connected to the second board. For example, some pins may be provided at the surface of the molded plastic for test, programming, or diagnostic purposes.

In various embodiments of the present invention, these interposers and pin arrays may be placed in various locations on a system-in-a-package module. For example, an interposer may be placed along a side of the module. In other embodiments of the present invention, the interposer may be placed in a corner, in middle, or other location on a module.

It should be noted that while the interconnect structures described above are well-suited to forming interconnect paths for system-in-a-package modules, in other embodiments of the present invention, other types of boards may be connected using these techniques. For example, other printed circuit boards that are not part of a system-in-a-package module may be electrically connected using these same or similar techniques and structures. For example, printed circuit boards may be attached to other boards, including printed circuit boards or flexible circuit boards, using the interposers and pins shown herein.

In various embodiments of the present invention, contacts, interconnect paths, and other conductive portions of interposers and pins may be formed by stamping, metal-injection molding, machining, micro-machining, 3-D printing, or other manufacturing process. The conductive portions may be formed of stainless steel, steel, copper, copper titanium, phosphor bronze, or other material or combination of materials. They may be plated or coated with nickel, gold, or other material. The nonconductive portions may be formed using injection or other molding, 3-D printing, machining, or other manufacturing process. The nonconductive portions may be formed of silicon or silicone, rubber, hard rubber, plastic, nylon, liquid-crystal polymers (LCPs), or other nonconductive material or combination of materials. The printed circuit boards used may be formed of FR-4, BT or other material. Printed circuit boards may be replaced by other substrates, such as flexible circuit boards, in many embodiments of the present invention, while flexible circuit boards may be replaced by printed circuit boards in these and other embodiments of the present invention.

Embodiments of the present invention may provide interconnect structures that may be located in and may connect to various types of devices, such as portable computing devices, tablet computers, desktop computers, laptops, all-in-one computers, wearable computing devices, cell phones, smart phones, media phones, storage devices, portable media players, navigation systems, monitors, power supplies, adapters, remote control devices, chargers, and other devices. In various embodiments of the present invention, these interconnect paths provided by these interposers and pins may be used to convey power, ground, signals, test points, and other voltage, current, data, or other information.

Various embodiments of the present invention may incorporate one or more of these and the other features described herein. A better understanding of the nature and advantages of the present invention may be gained by reference to the following detailed description and the accompanying drawings.

### BRIEF DESCRIPTION OF THE DRAWINGS

FIG. 1 illustrates a portion of an electronic device according to an embodiment of the present invention;

FIG. 2 illustrates a portion of an electronic device according to an embodiment of the present invention;

FIG. 3 illustrates top and bottom surfaces of an interposer according to an embodiment of the present invention;

FIG. 4 illustrates a step in a method of manufacturing a portion of an electronic device according to an embodiment of the present invention;

FIG. 5 illustrates a step in a method of manufacturing a portion of an electronic device according to an embodiment of the present invention;

FIG. 6 illustrates a step in a method of manufacturing a portion of electronic device according to an embodiment of the present invention;

FIG. 7 is a flowchart of a method of manufacturing a portion of an electronic device according to an embodiment of the present invention;

FIG. 8 illustrates a portion of an electronic device according to an embodiment present invention;

FIG. 9 illustrates a portion of an electronic device according to an embodiment of the present invention;

FIG. 10 illustrates a location of an interposer in a system-in-a-package module according to an embodiment of the present invention;

FIG. 11 illustrates a location of an interposer in a system-in-a-package module according to an embodiment of the present invention;

FIG. 12 illustrates a portion of an electronic device according to an embodiment of the present invention;

FIG. 13 illustrates a step and a method of manufacturing a portion of an electronic device according to an embodiment of the present invention;

FIG. 14 illustrates a step in a method of manufacturing a portion of an electronic device according to an embodiment of the present invention;

FIG. 15 illustrates a step in a method of manufacturing a portion of an electronic device according to an embodiment of the present invention; and

FIG. 16 illustrates a method of manufacturing a portion of electronic device according to an embodiment of the present invention.

### DESCRIPTION OF EXEMPLARY EMBODIMENTS

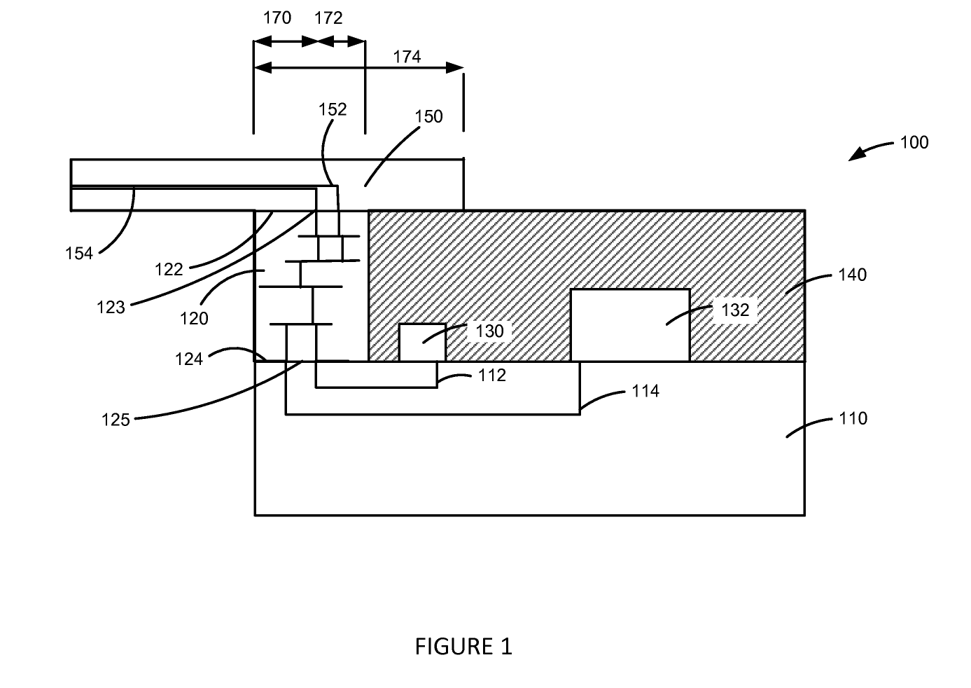

FIG. 1 illustrates a portion of an electronic device according to an embodiment of the present invention. This figure, as with the other included figures, is shown for illustrative purposes and does not limit either the possible embodiments of the present invention or the claims. This figure illustrates portion 100 of an electronic device including interposer 120 that may provide interconnect paths between first board 110 and second board 150.

First board 110 may include traces or other interconnect paths, represented here by traces 112 and 114. First board 110 may be a printed circuit board, flexible circuit board, or other appropriate substrate. For example, first board 110 may be a multi-layer printed circuit board. Electronic devices, circuits, or components 130 and 132 may be mounted on a top surface of board 110. Electronic devices, circuits, or components 130 and 132 may be surface mount components, though in this and the other examples they may be other types of devices, such as through-hole components. Devices, circuits, or components 130 and 132 may be active or passive components, integrated circuits, or other components or devices. Traces 112 and 114 may be electrically connected to devices, circuits, or components 130 and 132.

Interposer 120 may be attached to a top surface of board 110 at the same time as devices, circuits, or components 130 and 132, or interposer 120 may be attached to a top surface of board 110 at a different time. In various embodiments of the present invention, interposer 120 may be arranged such that it may be handled as a surface mount device. For example, contacts 125 on a bottom surface 124 of interposer 120 may be formed as a ball grid array to facilitate the handling of interposer 120 as a surface mount device. Contacts 125 on bottom surface 124 of interposer 120 may electrically connect to traces on the first board, such as traces 112 and 114. Interposer 120 may provide interconnect paths from first contacts 125 on bottom side 124 of the interposer 120 to second contacts 123 on a top side 125. Interposer 120 may include one or more layers. The interposer may include interconnect paths that may be formed of contacts or traces along surfaces of the layers and the traces may be coupled together by vias between the layers.

A molding or plastic encapsulation 124 may be formed around devices, circuits, or components 130 and 132 and a long one or more edges of interposer 120, though in other embodiments of the present invention, such molding may be absent. A top surface of the encapsulation 140 may be approximately aligned with the top surface 122 of interposer 120.

A second board 150 may be attached to the top surface 122 of interposer 120. Contacts 130 may be electrically connected to traces 152 and 154 on or in second board 150. Second board 150 may be a flexible circuit board, printed circuit board, or other appropriate board or substrate. Second board 150 may provide an interconnect path to other circuits or components in or associated with the electronic device.

Interposer 120 may provide a highly configurable interconnect structure. Specifically, contacts 125 and 122 and interconnect traces connecting them may be moved or changed using conventional printed circuit board manufacturing techniques.

Interposer 120 may also provide a highly space efficient interconnect structure. For example, flexible circuit board 150 may otherwise be attached directly to a surface of board 110. However, manufacturing tolerances may require a space between second board 150 and the encapsulation 140. In this example, this space is shown as distance 172. Given this distance, only length 170 of the first board 120 would remain for forming an attachment between second board 150 and first board 110. This limited space may make such an attachment difficult, for example where a hot-bar soldering processes is used.

Accordingly, embodiments of the present invention may provide interposer 120 and may further allow second board 150 to at least be aligned with a vertical edge, or overlap at least a portion of encapsulation 140. This provides a length 174 over which second board 150 may be attached to interposer 120. With length 174, a connection using a process such as a hot-bar process may be more readily completed. Again, in other embodiments of the present invention, other process steps, such as surface mount techniques, anisotropic conductive film, or other attachment methods or structures may be used.

In this and other embodiments of the present invention, contacts 124 may be formed using a ball grid array or other techniques. These techniques may be well-suited to providing a high density of contacts. This high density may be difficult to replicate in connecting a top surface 122 of interposer 120 to a second board 150. Accordingly, interposer 120 may be notched or stepped such that interposer 120 has a top surface 122 that is larger than a bottom surface 124. An example is shown in the following figure.

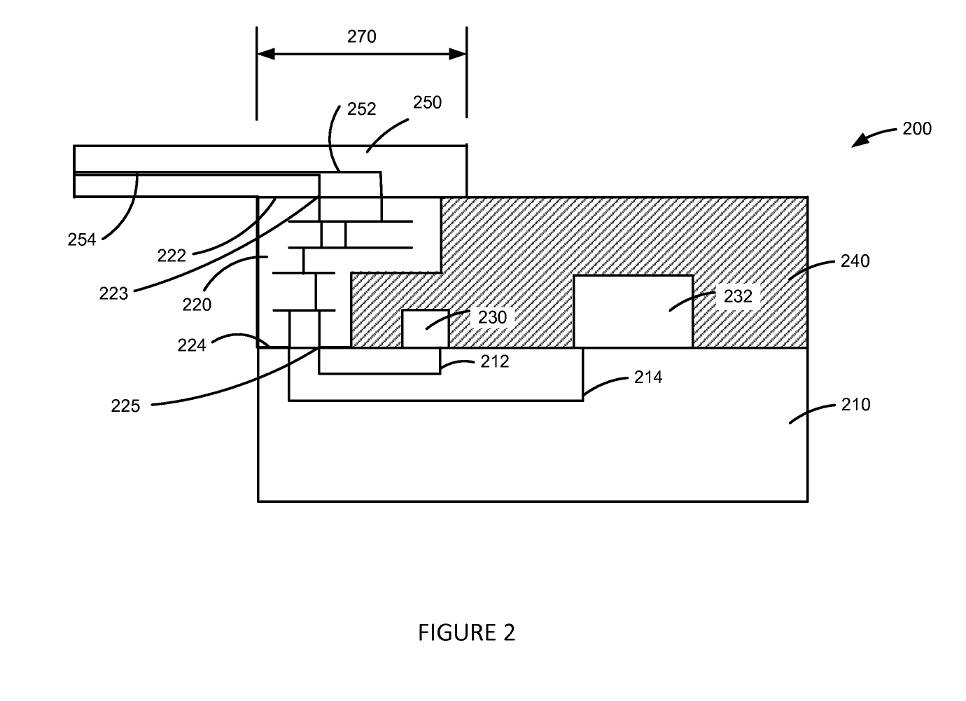

FIG. 2 illustrates a portion of an electronic device according to an embodiment of the present invention. As before, first board 210 may include traces 212 and 214. Traces 212 and 214 may electrically connect to devices, circuits, or components 230 and 232, which may be surface mounted on a top side of first board 210.

Interposer 220 may have a bottom surface 224 attached to a top surface of first board 210. Contacts 225 on a bottom surface 224 of interposer 220 may electrically connect to traces 212 and 214. Interposer 220 may be formed of one or more layers. Interposer 220 may include conductive paths between contacts 225 on a bottom surface 224 to contacts 223 on a top surface 222. These interconnect paths may include contacts or traces along one or more layers of interposer 220. These contacts or traces may be interconnected by vertical vias between the layers.

Devices, circuits, or components 230 and 232 may be encapsulated in a plastic molding 240 that may be defined along at least a portion of one edge by interposer 220, though again molding 240 may be absent in various embodiments of the present invention. Interposer 220 may be stepped such that top surface 222 may be larger than bottom surface 224. This step may provide a portion of encapsulation 240 having a lower height. Properly sized devices, circuits, or components, shown here as 230, may be placed in this shallow or lower-height area in order to more fully utilize space on a board 210.

Contacts 223 at top surface 222 of interposer 220 may electrically connect to traces 252 and 254 in second board 250. As before, first board 210 may be a printed circuit board, flexible circuit board, or other appropriate substrate, while second board 250 may be a flexible circuit board, printed circuit board, or other appropriate board. Second board 250 may be connected to other circuits or components in or associated with the electronic device.

As before, this embodiment of the present invention may provide a larger area that may simplify an attachment of a second board 250 to interposer 220. In this example, second board 250 may overlap at least a portion of encapsulation 240, such that length 270 is available for a hot bar during a hot-bar attachment of second board 250 to interposer 220.

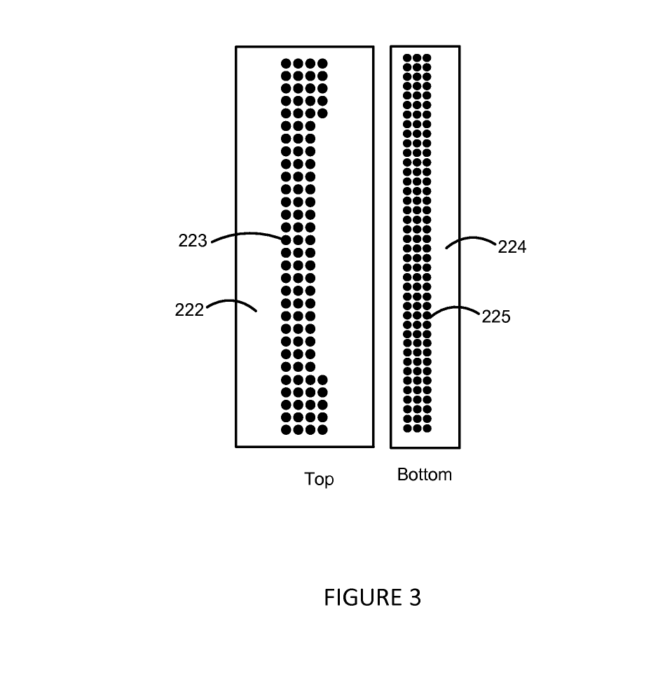

FIG. 3 illustrates top and bottom surfaces of an interposer according to an embodiment of the present invention. In this figure, top surface 222 may include contacts 223 while a bottom surface 224 may include contacts 225. Again, contacts 223 on top surface 222 may be larger than contacts 225 on bottom surface 224. Top surface 222 may include more contacts than bottom surface 224. This may be useful where one ground contact on a bottom surface 224 may be connected to two or more ground contacts on the top surface 222. This may improve shielding, reduce ground resistance, or be used other reasons. Contacts 223 and 225 may convey power, ground, data, test points, or other signals, voltages, currents, or other information.

Embodiments of the present invention may be manufactured using various techniques. One such technique is outlined in the following figures.

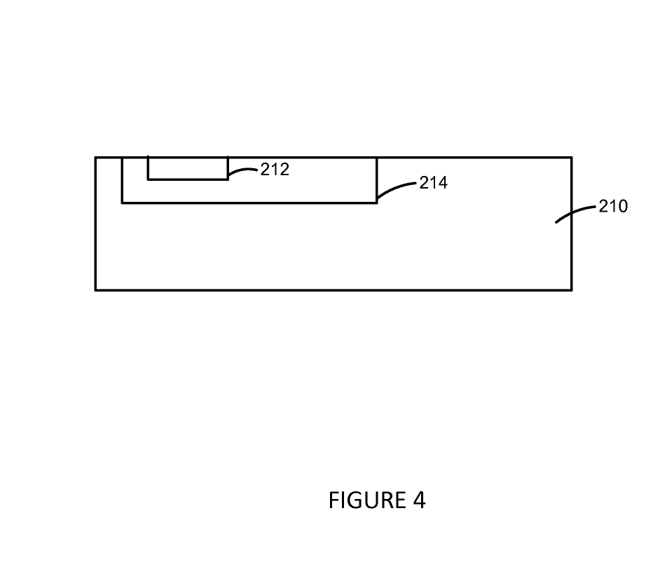

FIG. 4 illustrates a step in a method of manufacturing a portion of an electronic device according to an embodiment of the present invention. In this figure, a first board 210 having interconnect traces 212 and 214 may be provided. Interconnect traces 212 and 214 may be representative of traces that may be on or in printed circuit board 210.

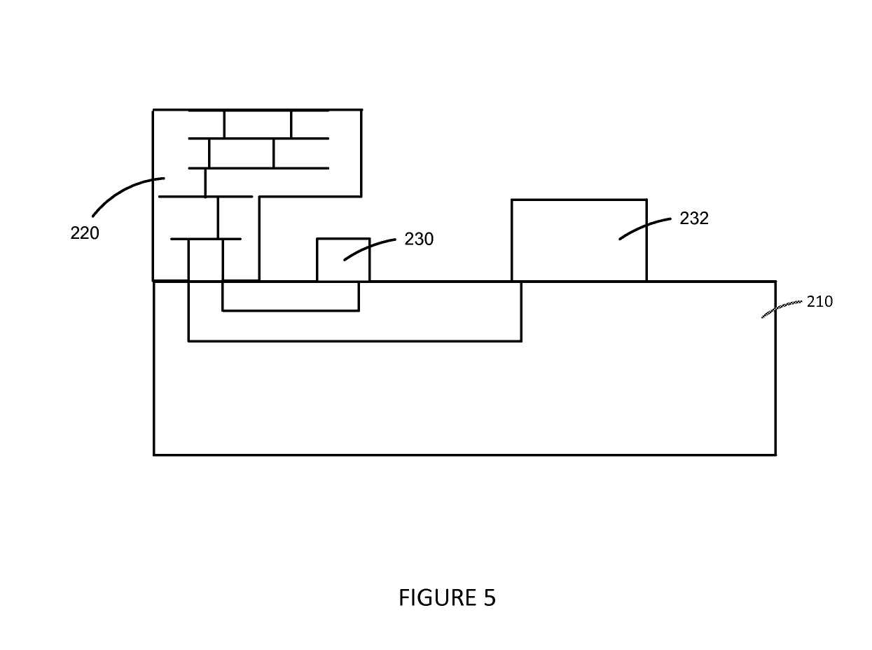

FIG. 5 illustrates a step in a method of manufacturing a portion of an electronic device according to an embodiment of the present invention. In this figure, devices, circuits, or components 230 and 232, as well as interposer 220, may be attached to a surface of first board 210. Devices, circuits, or components 230 and 232 may be surface mount devices. Again, interposer 220 may also be, or may be treated as, a surface mount device. Again, devices, circuits, or components 230 and 232 may be electrically connected to interposer 220 through traces on a first board 210. In this and the other examples herein, one or more devices, circuits, or components 230 and 232 and interposer 220 may be other types of device, such as through-hole devices.

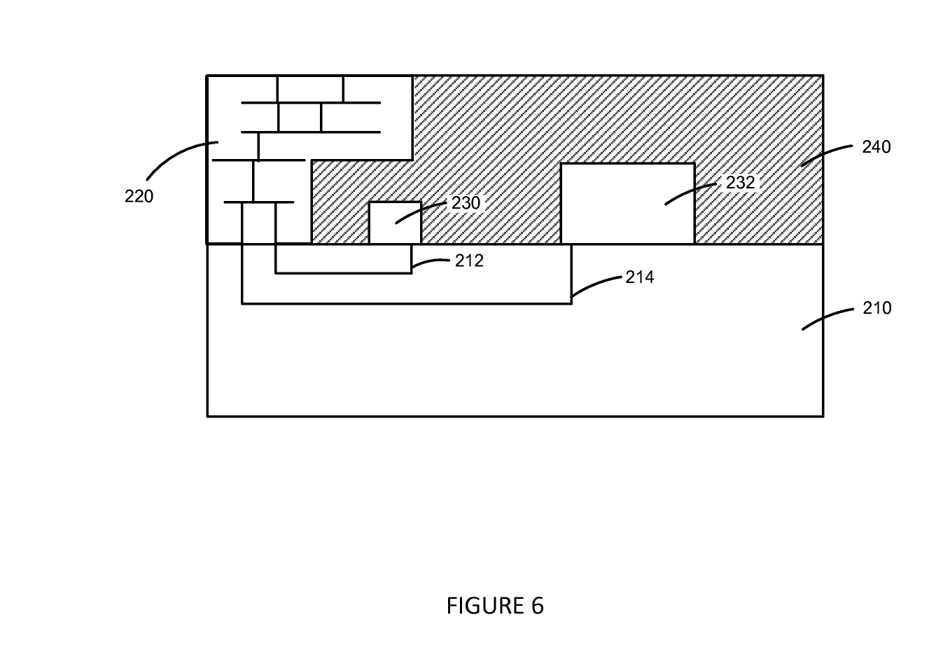

FIG. 6 illustrates a step in a method of manufacturing a portion of electronic device according to an embodiment of the present invention. In this figure, plastic encapsulation 240 may be formed or molded around devices, circuits, or components 230 and 232, and along at least an edge of interposer 220. A top surface of molding 240 may be at least approximately aligned with a top surface of interposer 220. Once the plastic encapsulation is complete, second board 250 may be attached as shown in FIG. 2. Again, in various embodiments of the present invention, molding 240 may be absent or optional.

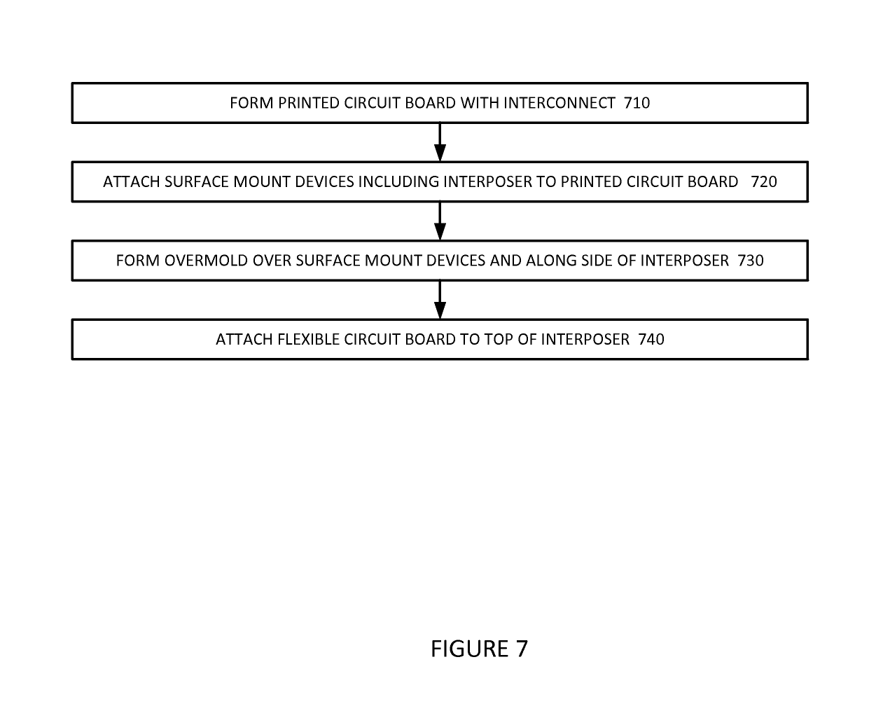

FIG. 7 is a flowchart of a method of manufacturing a portion of an electronic device according to an embodiment of the present invention. A printed circuit board having interconnect traces may be formed in act 710. In act 720, surface mount devices including an interposer may be attached to a top surface of printed circuit board. A plastic overmold or encapsulation over the surface mount devices and along at least a side of the interposer may be formed in act 730. In act 740, a flexible circuit board may be attached to a top surface of the interposer.

In the above example, interposer 220 may be notched or stepped such that plastic encapsulation 240 is also notched or stepped. In other embodiments of the present invention, the interposer may be notched or stepped such that it has a portion over the plastic encapsulation. An example is shown in the following figure.

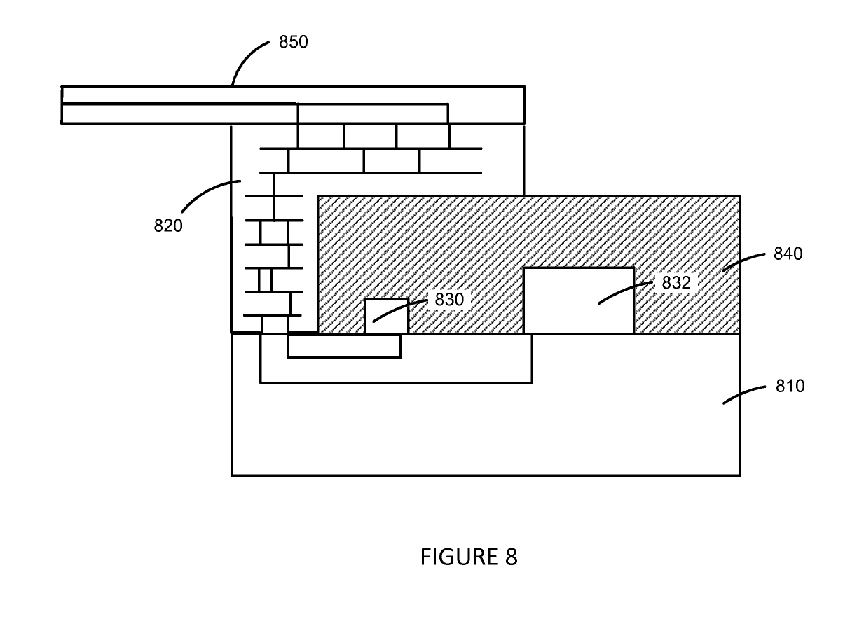

FIG. 8 illustrates a portion of an electronic device according to an embodiment present invention. In this example, devices, circuits, or components 830 and 832 may be mounted to a top surface of a first board 810. Devices, circuits, or components 830 and 832 may be encapsulated in a plastic encapsulation 840. An interposer 820 may be placed along an edge and over a top of the encapsulation 840. Second board 850 may be attached to a top surface of interposer 820. While interposer 820 is shown as overhanging molded portion 840, in other embodiments of the present invention, interposer 820 may overhang other devices or circuits, such as a packaged integrated circuit.

In still other embodiments of the present invention, a flexible circuit board or other interconnect structure may be formed as part of the interposer. An example is shown in the following figure.

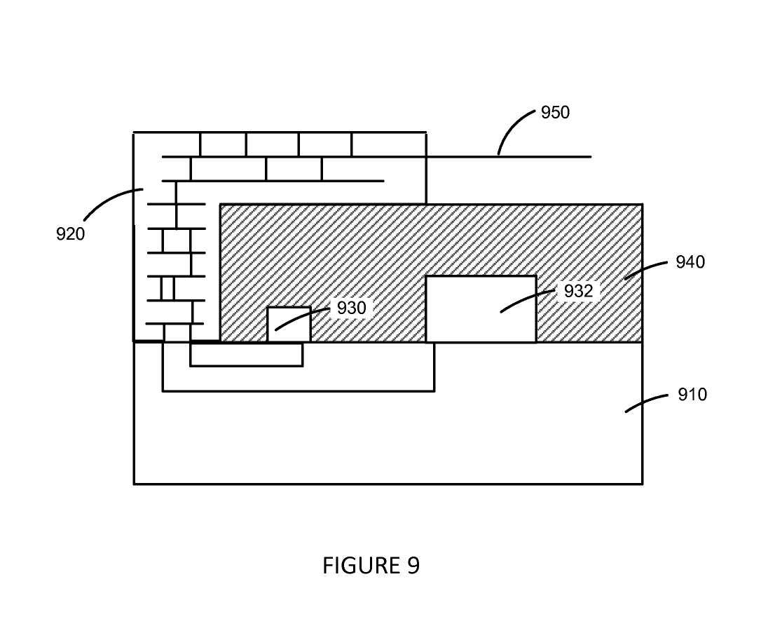

FIG. 9 illustrates a portion of an electronic device according to an embodiment of the present invention. As before, devices, circuits, or components 930 and 932 may be attached to a top surface of first board 910 and covered in plastic encapsulation 940. Intermediate layers of interposer 920 may be used to form flexible circuit board 950. Flexible circuit board 950 may connect to other components and circuits in or associated with the electronic device.

These interposers and other interconnect structures consistent with embodiments of the present invention may be located in different places on system-in-a-package modules. Examples are shown in the following figures.

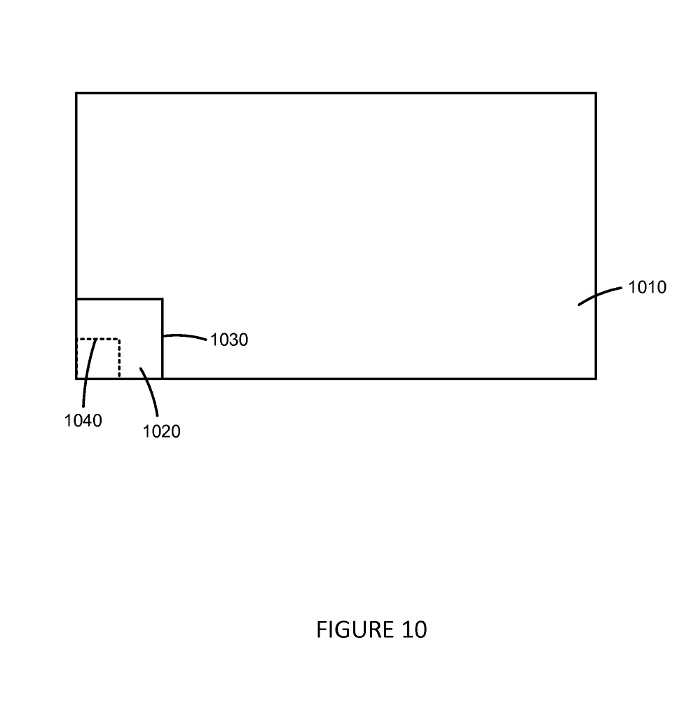

FIG. 10 illustrates a location of an interposer in a system-in-a-package module according to an embodiment of the present invention. Interposer 1020 may have a bottom surface 1040 and a top surface 1030. Interposer 1020 may be located in a corner of system-in-a-package module 1010.

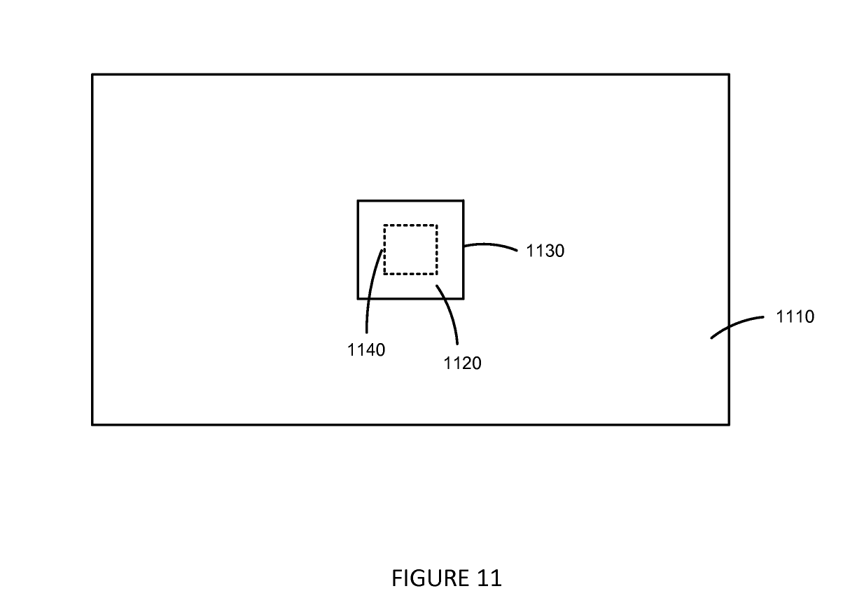

FIG. 11 illustrates a location of an interposer in a system-in-a-package module according to an embodiment of the present invention. Interposer 1120 may have a bottom surface 1140 and a top surface 1130. Interposer 1120 may be located in a center of a system-in-a-package module 1110. In still other embodiments of the present invention, these interposers may be located along an edge of a module, along two or more edges of a module, or they may be distributed in more than one location in a module. Also, while interposers may be located in these areas, other interconnect structures, such as the pins described below, may be placed in these or similar locations.

In still other embodiments of the present invention, other interconnect structures may be used in place of an interposer. For example, one or more pins, which may be distributed throughout a system-in-a-package module or arranged as a group or array on the module, may be used as an interconnect structure. An example is shown in the following figures.

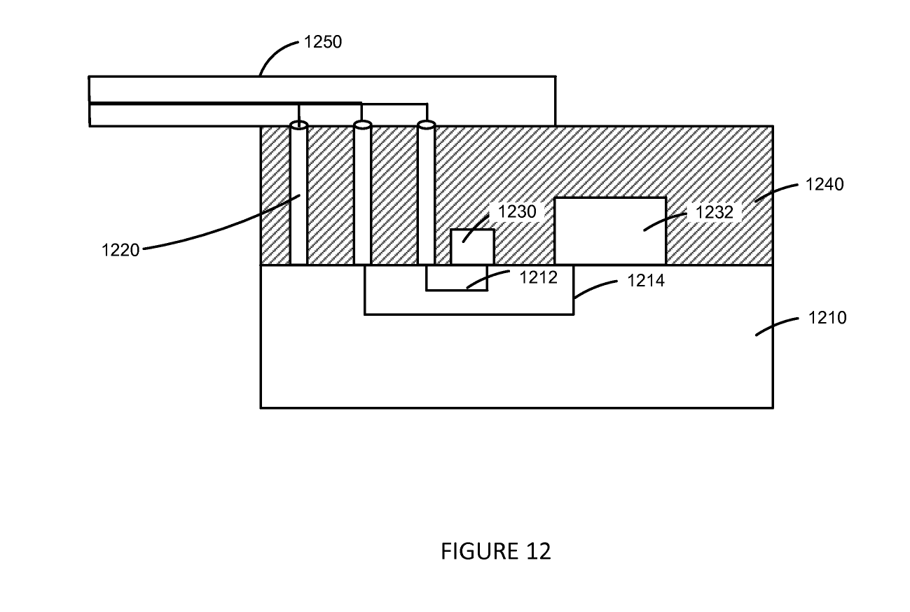

FIG. 12 illustrates a portion of an electronic device according to an embodiment of the present invention. As before, devices, circuits, or components 1230 and 1232 may be attached to a top surface of a first board 1210. Interconnect traces 1212 and 1214 may electrically connect devices, circuits, or components 1230 and 1232 to pins 1220. Pins 1220 may provide electrical connections to traces in second board 1250. A plastic housing or encapsulation 1240 may surround devices, circuits, or components 1230 and 1232 and pins 1220.

In this way, devices, circuits, or components 1230 and 1232 may electrically connect to traces in second board 1250 via interconnect traces 1212 and 1214 and pins 1220.

The above interconnect structure may be formed in various ways. One example is shown in the following figures.

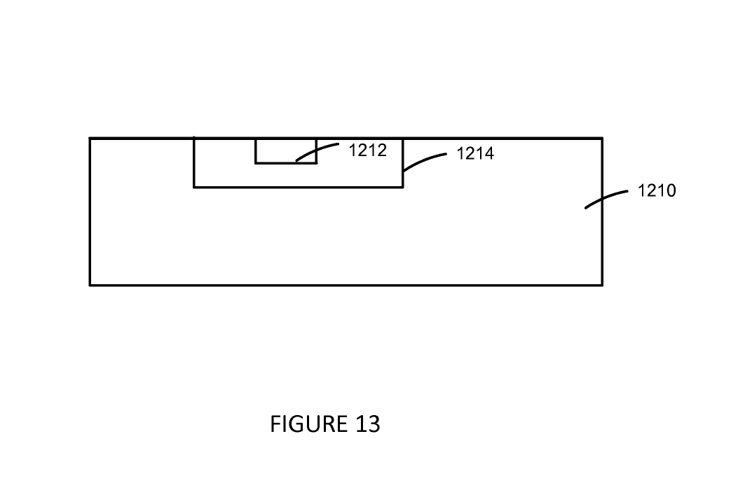

FIG. 13 illustrates a step and a method of manufacturing a portion of an electronic device according to an embodiment of the present invention. In this figure, a first board 1210 having interconnect traces, illustrated here as interconnect traces 1212 and 1214, may be provided. Interconnect traces 1212 and 1214 may be located in or on first board 1210. First board 1210 may be a printed circuit board, flexible circuit board, or other appropriate substrate.

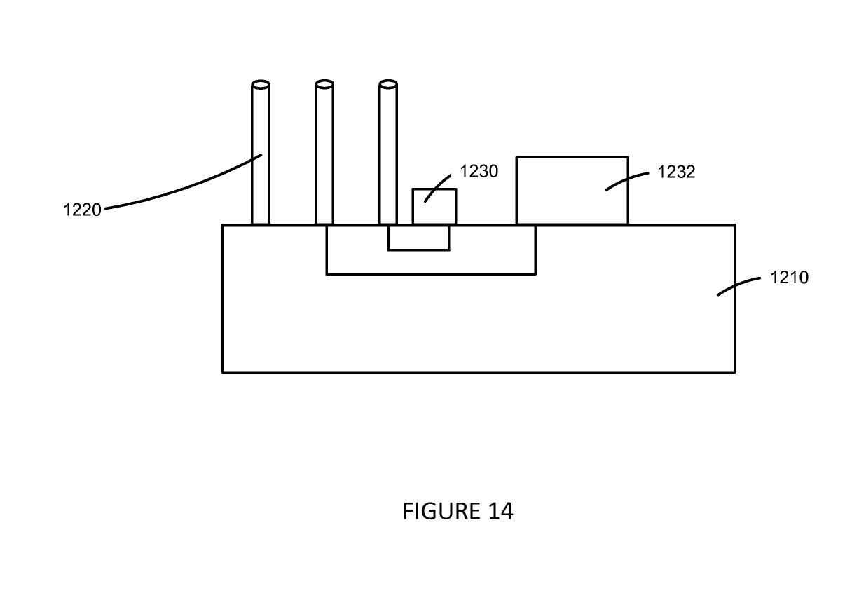

FIG. 14 illustrates a step in a method of manufacturing a portion of an electronic device according to an embodiment of the present invention. In this example, devices, circuits, or components 1230 and 1232 may be attached to a top surface of first board 1210. One or more pins 1220 may also be attached. These pins may be attached in a group or they may be distributed throughout a surface of first board 1210.

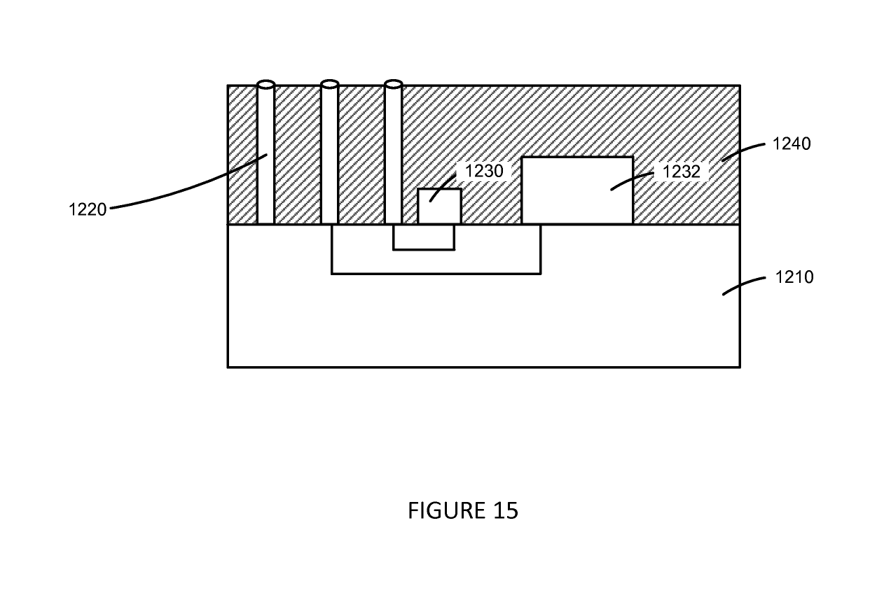

FIG. 15 illustrates a step in a method of manufacturing a portion of an electronic device according to an embodiment of the present invention. In this example, plastic encapsulation 1240 is placed over devices, circuits, or components 1230 and 1232 and around pins 1220. Top surfaces of pins 1220 may be exposed. This may require a top surface of plastic encapsulation 1240 to be etched, laptop or otherwise reduced or lowered. Once this is completed, circuit board 1250 may be attached as shown in FIG. 12. In various embodiments of the present invention, not all pins 1220 are connected to second board 1250. For example, some pins 1220 may be provided at the surface of the molded plastic or encapsulation 1240 for test, programming, or diagnostic purposes.

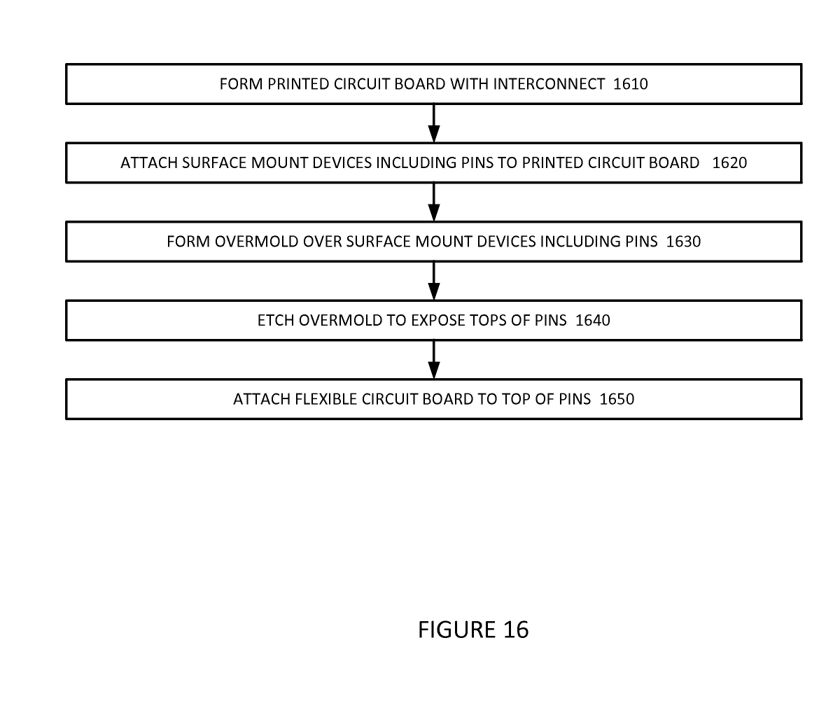

FIG. 16 illustrates a method of manufacturing a portion of electronic device according to an embodiment of the present invention. In act 1610, a printed circuit board having a number of interconnect traces may be formed. Surface mount devices including pins may be attached to a top surface of a printed circuit board in act 1620. An overmold over the surface mount devices and around the pins may be formed in act 1630. In act 1640, the overmold may be etched, lapped, or otherwise reduced to expose the top of the pins. A flexible circuit board may be attached to the tops of the pins in act 1650.

It should be noted that while the interconnect structures such as the interposers and pins shown above, are well-suited to forming interconnect paths for system-in-a-package modules, in other embodiments of the present invention, other types of boards may be connected using these techniques. For example, other printed circuit boards that are not part of a system-in-a-package module may be electrically connected using these same or similar techniques and structures.

In various embodiments of the present invention, contacts, interconnect paths, and other conductive portions of interposers and pins may be formed by stamping, metal-injection molding, machining, micro-machining, 3-D printing, or other manufacturing process. The conductive portions may be formed of stainless steel, steel, copper, copper titanium, phosphor bronze, or other material or combination of materials. They may be plated or coated with nickel, gold, or other material. The nonconductive portions may be formed using injection or other molding, 3-D printing, machining, or other manufacturing process. The nonconductive portions may be formed of silicon or silicone, rubber, hard rubber, plastic, nylon, liquid-crystal polymers (LCPs), or other nonconductive material or combination of materials. The printed circuit boards used may be formed of FR-4, BT or other material. Printed circuit boards may be replaced by other substrates, such as flexible circuit boards, in many embodiments of the present invention, while flexible circuit boards may be replaced by printed circuit boards in these and other embodiments of the present invention.

Embodiments of the present invention may provide interconnect structures that may be located in and may connect to various types of devices, such as portable computing devices, tablet computers, desktop computers, laptops, all-in-one computers, wearable computing devices, cell phones, smart phones, media phones, storage devices, portable media players, navigation systems, monitors, power supplies, adapters, remote control devices, chargers, and other devices. In various embodiments of the present invention, these interconnect paths provided by these interposers and pins may be used to convey power, ground, signals, test points, and other voltage, current, data, or other information.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

1. An electronic device comprising:
a first board comprising a plurality of traces;
a plurality of surface mount devices attached to a top surface of the first board, the plurality of surface mount devices electrically connected to traces in the plurality of traces;
an interposer attached to the top surface of the first board, the interposer having first contacts on a bottom surface electrically connected to traces in the plurality of traces, the interposer having a plurality of interconnect paths from the first contacts on the bottom surface to second contacts on a top surface; and
a second board having a plurality of traces electrically connected to the second contacts on the top surface of the interposer.

2. The electronic device of claim 1 further comprising a molded portion over the plurality of surface mount devices on the top surface of the first board and along a side of the interposer.

3. The electronic device of claim 1 wherein the interposer comprises a printed circuit board including a plurality of layers.

4. The electronic device of claim 3 wherein the interposer interconnect paths are comprised of traces on at least one layer and vias between at least two layers.

5. The electronic device of claim 1 wherein the surface mount devices comprise at least one integrated circuit.

6. The electronic device of claim 1 wherein the first board is a printed circuit board and the second board is a flexible circuit board.

7. The electronic device of claim 6 wherein the top surface of the interposer is larger than the bottom surface of the interposer.

8-20. (canceled)

21. The electronic device of claim 2 wherein the second board at least partially overlaps the molded portion.

22. The electronic device of claim 3 wherein the interposer interconnect paths are comprised of traces on a plurality of layers and vias between at least two of the plurality of layers.

23. The electronic device of claim 1 wherein the second contacts are larger than the first contacts.

24. The electronic device of claim 2 wherein at least one of the plurality of surface mount devices is under a portion of the interposer.

25. The electronic device of claim 2 wherein the second board at least partially overlaps a top surface of the molded portion.

26. The electronic device of claim 1 further comprising:
a plurality of pins having a first end attached to the top surface of the first board, the pins extending vertically and having second ends electrically connected to plurality of traces of the second board.

27. An electronic device comprising:
a first board comprising a plurality of traces;
a plurality of surface mount devices attached to a top surface of the first board, the plurality of surface mount devices electrically connected to traces in the plurality of traces;
an interposer attached to the top surface of the first board, the interposer having first contacts on a bottom surface of a bottom layer electrically connected to traces in the plurality of traces, the interposer having a plurality of interconnect paths from the first contacts on the bottom surface to second contacts on a top surface of a top layer, where the top layer is wider than the bottom layer;
a molded portion over the plurality of surface mount devices on the top surface of the first board and along a side of the interposer; and
a second board having a plurality of traces electrically connected to the second contacts on the top surface of the interposer.

28. The electronic device of claim 27 wherein the second board at least partially overlaps the molded portion.

29. The electronic device of claim 27 wherein the second contacts are larger than the first contacts.

30. The electronic device of claim 27 wherein at least one of the plurality of surface mount devices is under the top layer of the interposer.

31. The electronic device of claim 27 wherein each horizontal side of the interposer is in contact with the molded portion.

32. The electronic device of claim 27 wherein the second board at least partially overlaps a top surface of the molded portion.

33. The electronic device of claim 27 further comprising:
a plurality of pins having a first end attached to the top surface of the first board, the pins extending vertically and having second ends electrically connected to plurality of traces of the second board.
